(19) United States
(12) Patent Application Publication
(10) Pub. No.: US 2014/0151853 A1
(43) Pub. Date: Jun. 5, 2014

(54) Ion Implantation Apparatus, Ion Implantation Method, and Semiconductor Device

(71) Applicant: National University Corporation Tohoku University, Sendai-shi (JP)

(72) Inventors: Tadahiro OHMI, Sendai-shi (JP); Tetsuya GOTO, Sendai-shi (JP)

(73) Assignee: National University Corporation Tohoku University, Sendai-shi (JP)

(21) Appl. No.: 14/172,091

(22) Filed: Feb. 4, 2014

Related U.S. Application Data
(62) Division of application No. 13/139,335, filed on Jun. 13, 2011.

(30) Foreign Application Priority Data
Dec. 16, 2008 (JP) 2008-319269

(51) Int. Cl. H01L 21/67; H01L 21/265; H01L 21/223

(52) U.S. Cl. CPC H01L 21/67213; H01L 21/2236; H01L 21/26506
USPC 257/607; 438/513; 118/723 R

(57) ABSTRACT

In the plasma-based ion implantation for accelerating positive ions of a plasma and implanting the positive ions into a substrate to be processed on a holding stage in a processing chamber where the plasma has been excited, ion implantation is achieved in the following manner: an RF power having a frequency of 4 MHz or greater is applied to the holding stage to cause a self-bias voltage to generate on the surface of the substrate. The RF power is applied a plurality of times in the form of pulses.

### TECHNICAL FIELD

This invention relates to an ion implantation apparatus and an ion implantation method and, in particular, relates to an ion implantation apparatus and an ion implantation method for use in the manufacture of semiconductor devices such as ICs or LSIs. Further, this invention relates to a semiconductor device such as an IC or LSI, particularly to a MOS transistor formed on an SOI substrate.

### BACKGROUND ART

As shown in Non-Patent Document 1, plasma-based ion implantation is a technique that produces a plasma using a gas containing atoms to be implanted and, by applying a negative voltage to a workpiece substrate to be processed, accelerates positive ions in the sheath to carry out ion implantation into the workpiece substrate.

As compared with a conventional ion implantation method using an ion beam, the plasma-based ion implantation is at a low cost and further can produce a large amount of ions with a low energy of 10 keV or less, and therefore, it is advantageous when forming a shallow source/drain layer of a MOS transistor.

### PRIOR ART DOCUMENT

### Non-Patent Document

Non-Patent Document 1: J. R. Conrad, “Sheath thickness and potential profiles of ion-matrix sheaths for cylindrical and spherical electrodes”, J. Appl. Phys. vol. 62, (1987) pp. 777-779

### SUMMARY OF THE INVENTION

### Problem to be Solved by the Invention

In the plasma-based ion implantation disclosed in the above-mentioned Non-Patent Document, a negative high-voltage DC pulse of normally several tens of μs is applied to an electrode provided in a holding stage holding a workpiece substrate so that ions are accelerated and implanted into the workpiece substrate by an electric field that is transiently generated on a surface of the workpiece substrate immediately after the application of the DC pulse.

However, since the transient phenomenon is used in this method, the time constant of the transient phenomenon changes depending on the conductivity and permittivity of the workpiece substrate and thus it is difficult to precisely control the ion acceleration energy. As a consequence, it is also difficult to control the ion implantation distribution. In particular, in order to form a shallow source/drain junction in a MOS transistor manufacturing process, it is necessary to suppress diffusion of implanted impurity ions so that activation annealing at a low temperature of 600° C. or less is required. That is, an implantation distribution uniformalizing effect due to diffusion in high-temperature annealing cannot be used and thus there is required an ion implantation method that can precisely control the implantation distribution.

### Means for Solving the Problem

According to a first aspect of this invention, there is provided an ion implantation apparatus, comprising:

a processing chamber which is evacuated,

plasma exciting means for exciting a plasma in the processing chamber and,

a holding stage provided in the processing chamber and holding a substrate to be processed,

wherein an RF power is applied to the holding stage to generate a self-bias voltage on a surface of the substrate so that positive ions in the plasma are accelerated and implanted into the substrate,

wherein the RF power has a frequency of 4 MHz or more and is applied in the form of pulses so that ion implantation is dividedly carried out a plurality of times.

According to a second aspect of this invention, there is provided the ion implantation apparatus according to the first aspect, wherein the plasma exciting means comprises;

means for causing an electromagnetic wave having a frequency selected from a range of 100 MHz to 3 GHz to propagate as a metal surface wave into the processing chamber, and

means for introducing a gas for plasma excitation into the processing chamber.

According to a third aspect of this invention, there is provided the ion implantation apparatus according to the first or second aspect, wherein the holding stage has an electrostatic chuck function,

a gas is filled into a space between the holding stage and the substrate by the electrostatic chuck function,

a filling pressure of the gas is set higher than a pressure in the processing chamber, and

a shield plate is provided around the holding stage for preventing the gas leaking from the space from entering a plasma exciting region.

According to a fourth aspect of this invention, there is provided an ion implantation method that carries out ion implantation using the ion implantation apparatus according to any one of first to third aspects.

According to a fifth aspect of this invention, there is provided the ion implantation method according to the fourth aspect, wherein the ion implantation is carried out using at least a plurality of self-bias voltages by changing the RF power to be applied to the holding stage.

According to a sixth aspect of this invention, there is provided the ion implantation method according to the fifth aspect, wherein the surface of the substrate comprises a semiconductor crystal containing silicon, the method comprising a step of carrying out the ion implantation while amorphizing the semiconductor crystal by at least a first self-bias voltage, and a step of causing an ion implantation density of an outermost surface of the semiconductor crystal to be at least 1×10²⁰ cm⁻³ or more by a second self-bias voltage.

According to a seventh aspect of this invention, there is provided the ion implantation method according to any one of forth to sixth aspects, wherein the gas for plasma excitation is a gas of a fluoride of an implantation atom.

According to an eighth aspect of this invention, there is provided the ion implantation method according to any one of claims fourth to seventh aspects, wherein the gas for plasma excitation is at least one gas selected from the group comprising BF₃, PF₃, and AsF₃.

According to a ninth aspect of this invention, there is provided a semiconductor device, comprising:

a substrate having at least a first semiconductor region, a buried insulator layer formed on the first semiconductor region, and a second semiconductor region formed on the buried insulator layer,

wherein the second semiconductor region comprises a channel region and source/drain regions, and

a thickness of a layer of the second semiconductor region is such that a thickness of the layer of the source/drain regions is set to be twice or more that of the layer of the channel region.

According to a tenth aspect of this invention, there is provided the semiconductor device according to the ninth aspect, wherein the semiconductor device has an accumulation mode in which the channel region, the source region, and the drain region are of the same conductivity type.

According to an eleventh aspect of this invention, there is provided a semiconductor device manufactured using the ion implantation apparatus according to any one of the first to third aspects.

According to a twelfth aspect of this invention, there is provided a semiconductor device manufactured using the ion implantation method according to any one of forth to eighth aspects.

According to a thirteenth aspect of this invention, there is provided a semiconductor device manufacturing method, comprising:

a step of carrying out ion implantation by the ion implantation method according to any one of forth to eighth aspects.

### Effect of the Invention

According to this invention, there are obtained an ion implantation method and an ion implantation apparatus that can precisely control the ion acceleration energy and that can accurately control the implantation distribution when forming a shallow junction in a semiconductor.

### BRIEF DESCRIPTION OF THE DRAWINGS

FIG. 1 shows diagrams (a) and (b) respectively showing the implanted ion energy distribution and the depth-direction dependence of the implanted ion density when BF₂⁺ ions are implanted by plasma doping into a silicon substrate to form a p⁺-Si source/drain layer according to this invention.

FIG. 2 is a diagram showing a schematic structure of an ion implantation apparatus according to a first embodiment of this invention.

FIG. 3 shows a diagram (a) showing the energy dependence of the average implantation depth Rp and the width ΔRp for incident ions BF₂⁺, a diagram (b) showing the energy dependence of the average implantation depth Rp and the width ΔRp for incident ions PF₂⁺, and a diagram (c) showing the energy dependence of the average implantation depth Rp and the width ΔRp for incident ions AsF₂⁺.

FIG. 4 shows diagrams (a) and (b) respectively showing the implanted ion energy distribution and the depth-direction dependence of the implanted ion density when ion implantation is carried out by changing the frequency of the substrate RF power.

FIG. 5 shows diagrams (a) and (b) respectively showing the incident ion energy distribution and the incident ion implantation distribution when plasma excitation is carried out using a PF₃ gas so that PF₂⁺ ions are implanted.

FIG. 6 shows diagrams (a) and (b) respectively showing the incident ion energy distribution and the incident ion implantation distribution when the RF frequency is changed to 1 MHz, 2 MHz, 4 MHz, 6 MHz, and 10 MHz.

FIG. 7 is a cross-sectional view showing the structure of a semiconductor device according to a third embodiment of this invention.

FIG. 8 is a schematic diagram showing a partial structure of an ion implantation apparatus according to a fourth embodiment of this invention.

FIG. 9 is a longitudinal sectional view showing a schematic structure of one example of a plasma processing apparatus for use in this invention.

FIG. 10 is a transverse sectional view taken along line A-A of the plasma processing apparatus shown in FIG. 9.

FIG. 11 is a transverse sectional view taken along line B-B of the plasma processing apparatus shown in FIG. 9.

FIG. 12 is a transverse sectional view taken along line C-C of the plasma processing apparatus shown in FIG. 9.

### MODE FOR CARRYING OUT THE INVENTION

### First Embodiment

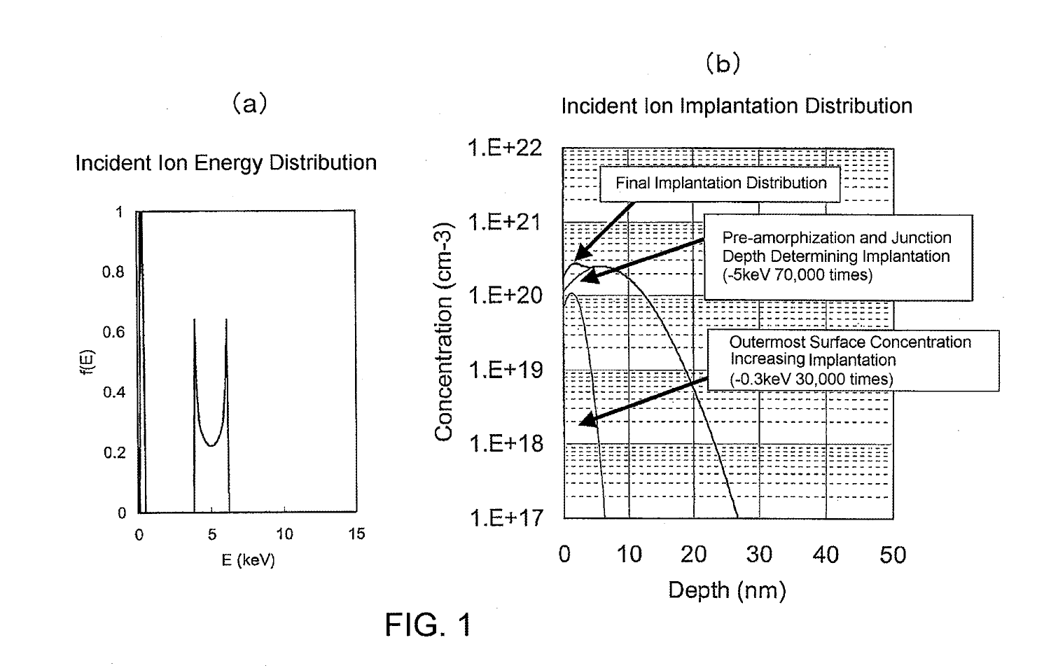

A first embodiment of this invention is shown. FIGS. 1 (a) and (b) respectively show the implanted ion energy distribution and the depth-direction dependence of the implanted ion density when BF₂⁺ ions are implanted by plasma doping into a silicon substrate to form a p⁺-Si source/drain layer according to this invention.

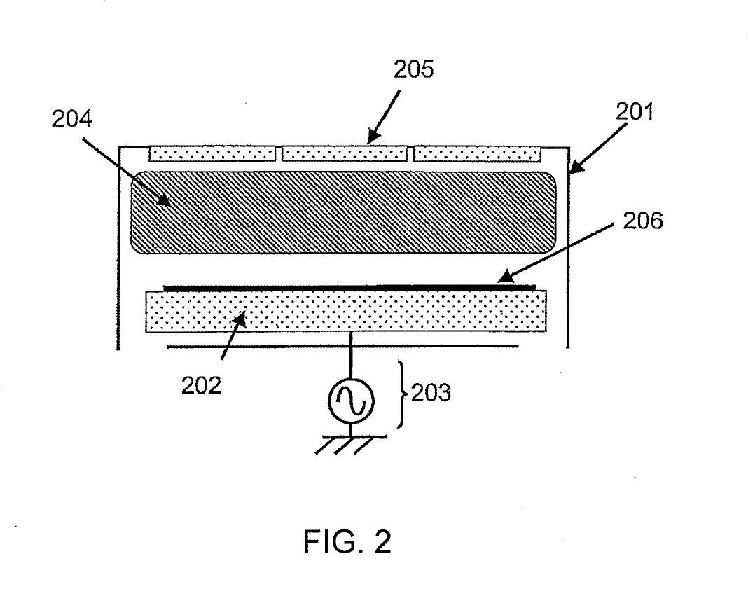

FIG. 2 shows a schematic structure of a plasma doping apparatus used in FIG. 1. Although details will be described later, 201 denotes a processing chamber, 202 a holding stage for placing thereon a silicon substrate 206, i.e. a substrate electrode stage, 203 a portion that generates RF power to be applied to the substrate electrode, 205 a conductor surface wave (metal surface wave) plasma excitation portion, and 204 an excited plasma. The processing chamber can be evacuated by a non-illustrated exhaust pump.

Normally, for stable plasma excitation, it is desirable to dilute a material gas with a noble gas such as Ar. However, in the case of carrying out ion implantation by plasma doping, if a material gas is diluted with a gas such as Ar, Ar ions are also implanted into a substrate, and therefore, it is desirable to carry out plasma excitation only with the material gas.

As the material gas, there is, for example, BF₃, PF₃, AsF₃, or the like. However, if such a gas is formed into a plasma, since F has a very large electronegativity, electrons tend to adhere thereto and thus a large amount of F⁻ ions are produced, resulting in a reduction in the electron density. Therefore, it is desirable to use a conductor surface wave (metal surface wave) excitation method that can stably maintain plasma excitation even at low electron density.

Taking this into account, the conductor surface wave (metal surface wave) method using a 915 MHz microwave is employed in this embodiment. Although a gas containing hydrogen, such as B₂H₆, can also be cited as a material gas, since hydrogen is a light atom, it is implanted into a substrate while being accelerated to very high energy, thus serving as a factor to cause damage. Therefore, it is desirable not to use the gas containing hydrogen.

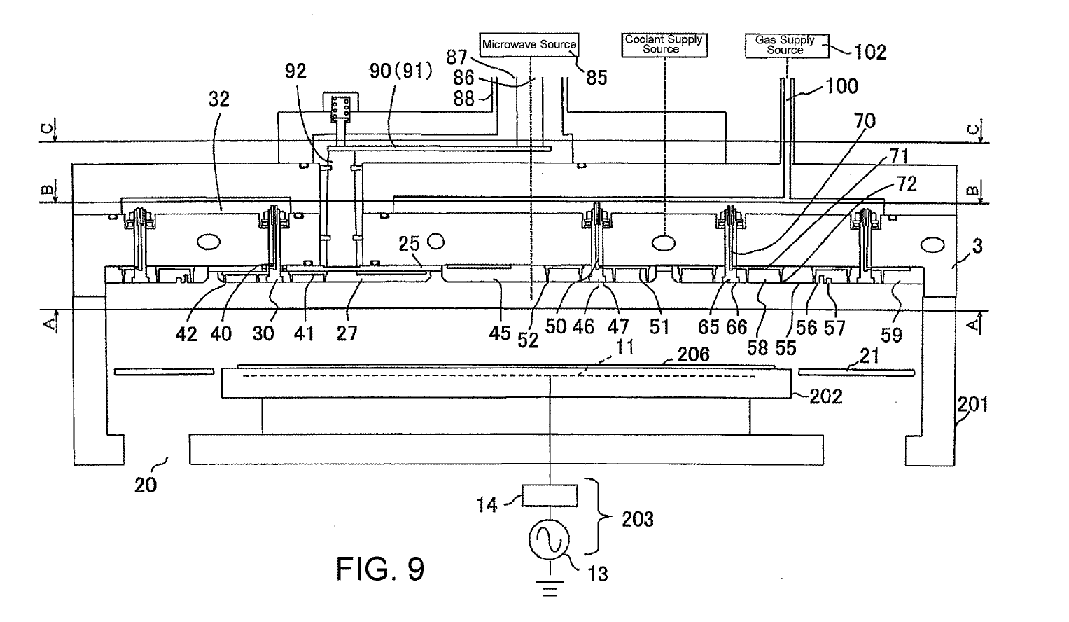

Herein, referring to FIGS. 9 to 12, a description will be given of an example of a conductor surface wave (metal surface wave) type plasma processing apparatus for use in this invention.

The conductor surface wave (metal surface wave) type plasma processing apparatus for use in this invention is a plasma processing apparatus comprising a processing vessel made of metal for placing therein a substrate to be subjected to a plasma treatment (plasma doping in this invention), a means for introducing into the processing vessel a gas necessary for exciting a plasma, and an electromagnetic wave source for supplying an electromagnetic wave necessary for exciting the plasma, and further comprising, on a lower surface of a cover of the processing vessel, a plurality of dielectrics partially exposed to the inside of the processing vessel for introducing the electromagnetic wave supplied from the electromagnetic wave source into the processing vessel. Further, the apparatus is configured such that metal electrodes are respectively provided on lower surfaces of the dielectrics so that the electromagnetic wave emitted from exposed portions of the dielectrics exposed between the metal electrodes and the lower surface of the cover propagates as a metal surface wave along the metal surfaces of both the metal electrodes and the lower surface of the cover, thereby exciting the above-mentioned gas to produce a plasma.

According to this structure, a plasma which is excited in the processing vessel by a conductor surface wave due to a microwave having a relatively low frequency of, for example, 915 MHz becomes uniform. As a result, the entire treatment surface of the substrate can be uniformly treated. Further, since it is possible to excite the plasma using the electromagnetic wave (conductor surface wave) propagating along the surface wave propagating portions arranged around the dielectrics, the amount of use of the dielectric can be largely reduced. Further, by reducing the exposed area of the dielectric exposed to the inside of the processing vessel, damage, etching, and so on of the dielectric due to overheating of the dielectric can be suppressed and, further, the occurrence of metal contamination from the inside of the processing vessel can be prevented. In particular, as compared with the case of using a microwave having a frequency of 3 GHz or more, the lower limit of the electron density for obtaining a stable, low electron temperature plasma can be set to about 1/7 (in the case of 915 MHz) and thus the plasma suitable for a plasma treatment can be obtained under conditions of a wider range which cannot be used so far. As a consequence, it is possible to significantly improve the flexibility of the processing apparatus.

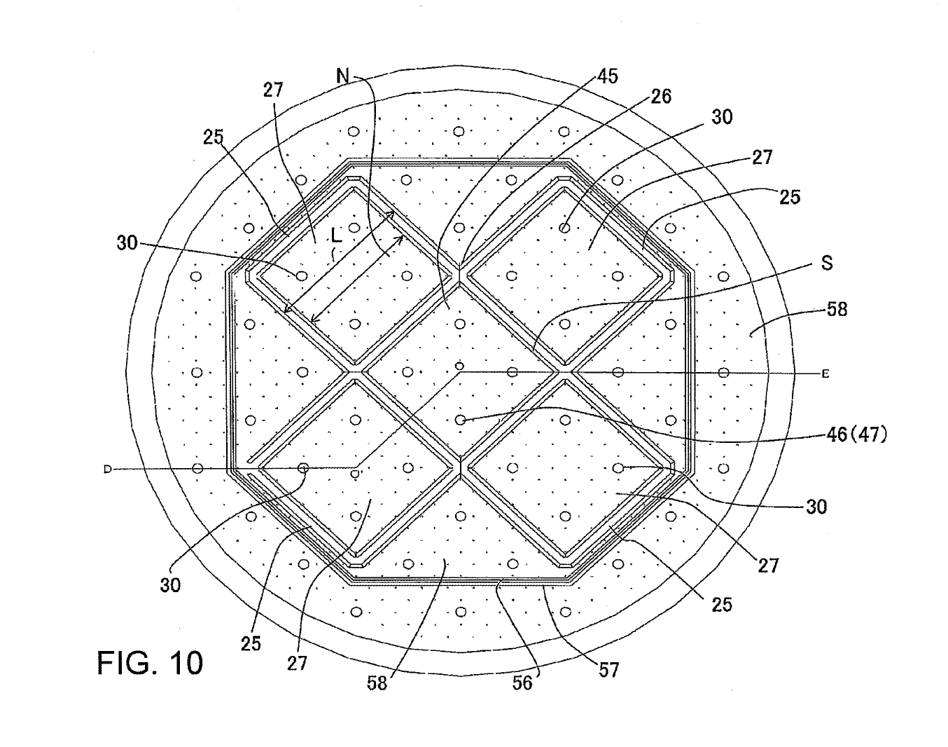

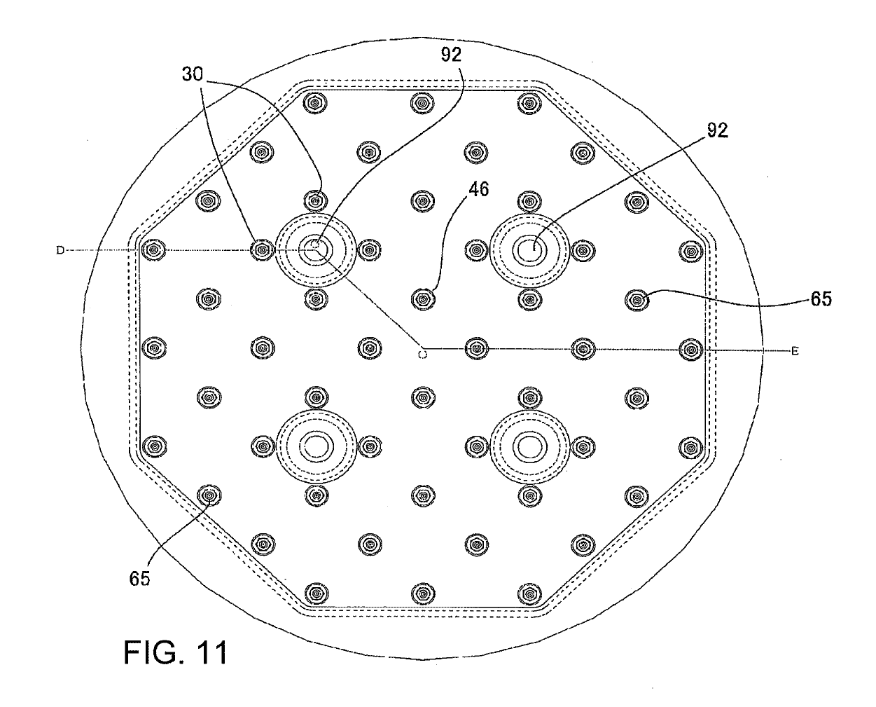

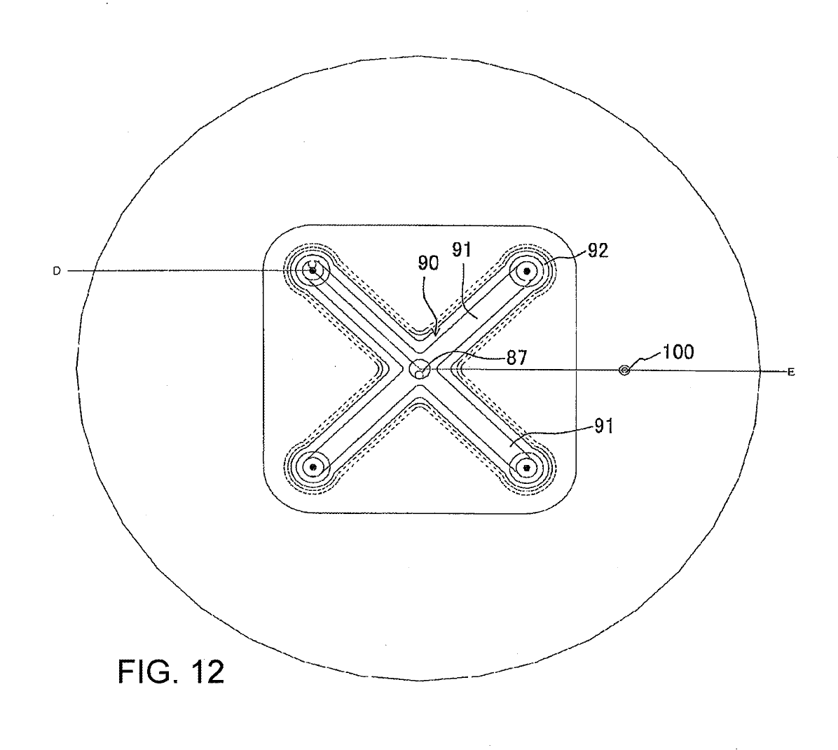

FIG. 9 is a longitudinal sectional view (D-O′-O-E section of FIGS. 10 to 12) showing a schematic structure of the example of the plasma processing apparatus for use in this invention. FIG. 10 is a transverse sectional view taken along line A-A of FIG. 9. FIG. 11 is a transverse sectional view taken along line B-B of FIG. 2. FIG. 12 is a transverse sectional view taken along line C-C of FIG. 9. This plasma processing apparatus comprises a hollow vessel body 201 and a cover 3 mounted over the vessel body 201. A closed space is formed inside the processing vessel 201. The processing vessel 201 and the cover 3 are made of a material having conductivity, for example, an aluminum alloy, and are electrically grounded.

A susceptor 202 as a placing stage for placing thereon a semiconductor substrate 206 is provided in the processing vessel 201. The susceptor 202 is made of, for example, aluminum nitride and is provided therein with a power feed portion 11 for applying a predetermined bias voltage to the substrate. A high-frequency power supply portion 203 for bias application provided outside the processing vessel is connected to the power feed portion 11. The illustrated high-frequency power supply portion 203 comprises a high-frequency power supply 13 and a matching device 14 having a capacitor and so on.

At the bottom of the processing vessel 201, an exhaust port 20 is provided for evacuating the inside of the processing vessel by the use of an exhaust device such as a vacuum pump (not illustrated) provided outside the processing vessel. Further, a baffle plate 21 is provided in the processing vessel 201 around the susceptor 202 for controlling the gas flow in a preferable state.

Four dielectrics 25 made of Al₂O₃, for example, are attached to a lower surface of the cover 3. A dielectric material such as, for example, fluororesin or quartz can alternatively be used as the dielectrics 25. As shown in FIG. 10, the dielectrics 25 are each in the form of a plate having the shape of a square or a quadrilateral close to a square. As shown in FIG. 10, these four dielectrics 25 are disposed so that their vertices (flat portions 26) are adjacent to each other.

A metal electrode 27 is attached to a lower surface of each dielectric 25. The metal electrode 27 is made of a material having conductivity, for example, an aluminum alloy. Like the dielectric 25, the metal electrode 27 is formed into a square plate shape. The width N of the metal electrode 27 is slightly smaller than the width L of the dielectric 25. Therefore, seeing from the inside of the processing vessel, the dielectric 25 is exposed around the metal electrode 27 in the state where the peripheral portion of the dielectric 25 appears with its square contour. Further, seeing from the inside of the processing vessel, the dielectrics 25 are disposed so that the vertices of the square contours formed by the peripheral portions of the dielectrics 25 are adjacent to each other.

The dielectrics 25 and the metal electrodes 27 are attached to the lower surface of the cover 3 by means of connecting members 30 such as screws.

A vertical gas flow path 40 is provided in each connecting member 30 at its central portion while lateral gas flow paths 41 are respectively provided between the dielectrics 25 and the metal electrodes 27. A plurality of gas ejection holes 42 are dispersedly opened at a lower surface of each metal electrode 27. A predetermined gas supplied into a space portion 32 in the cover 3 passes through the gas flow paths 40 and 41 and through the gas ejection holes 42 so as to be dispersedly supplied into the processing vessel 4.

As shown in FIG. 10, a metal cover 45 is attached to a region, surrounded by the four dielectrics 25, at the center of the lower surface of the cover 3. This metal cover 45 is made of a material having conductivity, for example, an aluminum alloy and is electrically connected to the lower surface of the cover 3 so as to be electrically grounded. That is, it can be regarded as a part of the cover. Like the metal electrode 27, the metal cover 45 is formed into a square plate shape having the width N. The metal cover 45 has a thickness approximately the same as the total thickness of the dielectric 25 and the metal electrode 27. As a consequence, a lower surface of the metal cover 45 and the lower surface of the metal electrode 27 are flush with each other. The metal cover 45 is attached to the lower surface of the cover 3 by means of connecting members 46 such as screws. Lower surfaces 47, exposed to the inside of the processing vessel, of the connecting members 46 are flush with the lower surface of the metal cover 45.

As shown in FIG. 9, a vertical gas flow path 50 is provided in each connecting member 46 at its central portion while a lateral gas flow path 51 is provided between the lower surface of the cover 3 and the metal cover 45. A plurality of gas ejection holes 52 are dispersedly opened at the lower surface of the metal cover 45. The predetermined gas supplied into the space portion 32 in the cover 3 passes through the gas flow paths 50 and 51 and through the gas ejection holes 52 so as to be dispersedly supplied into the processing vessel 4.

During a plasma treatment, a microwave propagating to the respective dielectrics 25 from a microwave supply device 85 propagates from the peripheral portions, exposed at the lower surface of the cover 3, of the dielectrics 25 along the lower surface of the metal cover 45, the lower surfaces of the metal electrodes 27, and a lower surface of a side cover inner portion 58. In this event, grooves 56 and 57 serve as a propagation barrier portion for preventing the microwave (conductor surface wave), propagating along the lower surface of the side cover inner portion 58, from propagating to the outside (side cover outer portion 59) beyond the grooves 56 and 57. As a consequence, the lower surface of the metal cover 45, the lower surfaces of the metal electrodes 27, and the lower surface of the side cover inner portion 58, which are regions surrounded by the grooves 56 and 57 at the lower surface of the cover 3, serve as surface wave propagating portions.

A side cover 55 is attached to the lower surface of the cover 3 by means of connecting members 65 such as screws. Lower surfaces 66, exposed to the inside of the processing vessel, of the connecting members 65 are flush with a lower surface of the side cover 55. A vertical gas flow path 70 is provided in each connecting member 65 at its central portion while a lateral gas flow path 71 is provided between the lower surface of the cover 3 and the side cover 55. A plurality of gas ejection holes 72 are dispersedly opened at the lower surface of the side cover 55. The predetermined gas supplied into the space portion 32 in the cover 3 passes through the gas flow paths 70 and 71 and through the gas ejection holes 72 so as to be dispersedly supplied into the processing vessel 4.

A coaxial tube 86 is connected to an upper surface of the cover 3 at its center for transmitting a microwave supplied from the microwave source 85 disposed outside the processing vessel 4. The coaxial tube 86 comprises an inner conductor 87 and an outer conductor 88. The inner conductor 87 is connected to a branching plate 90 disposed in the cover 3.

As shown in FIG. 12, the branching plate 90 is configured such that four branch conductors 91 are arranged in a cross shape with its center serving as the position of coupling to the inner conductor 87. A metal rod 92 is attached to a lower surface of each branch conductor 91 at its free end. These coaxial tube 86, branching plate 90, and metal rods 92 are formed of a conductive material such as Cu.

As a microwave having a frequency of 3 GHz or less, a microwave having a frequency of, for example, 915 MHz is introduced into the coaxial tube 86 from the microwave supply device 85. As a consequence, the 915 MHz microwave is branched by the branching plate 90 so as to be transmitted to the respective dielectrics 25 (FIGS. 9 and 10) through the metal rods 92.

A gas pipe 100 is connected to the upper surface of the cover 3 for supplying the predetermined gas necessary for the plasma treatment. Further, a coolant pipe 101 is provided in the cover 3 for supplying a coolant. The predetermined gas supplied through the gas pipe 100 from a gas supply source 102 disposed outside the processing vessel 4 is supplied into the space portion 32 in the cover 3 and then passes through the gas flow paths 40, 41, 50, 51, 70, and 71 and through the gas ejection holes 42, 52, and 72 so as to be dispersedly supplied into the processing vessel 4.

Referring to FIG. 1, an ion implantation method using the above-mentioned plasma-based ion implantation apparatus will be described hereinbelow. A BF₃ gas was introduced into the processing chamber of the ion implantation apparatus at a pressure of 100 mTorr and a 915 MHz microwave was introduced as a conductor surface wave (metal surface wave), thereby exciting a plasma to produce BF₂⁺ ions.

On the other hand, in order to generate a substrate bias, in this embodiment, 4 MHz RF power was applied with a pulse width of 10 μs and at an interval of 90 μs instead of using a DC pulse. That is, in this embodiment, use was made of RF power pulses in which the pulse width is shorter than the pulse stop period (herein, RF power pulses with a duty cycle of 1/10).

First, pulse application was carried out 70,000 times by setting the self-bias voltage to −5 kV and, successively, ion implantation was carried out 30,000 times by setting the self-bias voltage to −0.3 kV. The total implantation amount was set to 3×10¹⁴ cm⁻². Distribution thereof is shown in FIG. 1(b). Boron B is activated to a maximum density of 2×10²⁰ cm⁻³ with respect to Si and the resistance thereof decreases as its concentration increases. In general, with the miniaturization of MOS transistors for enhancing the performance thereof, it is necessary to reduce the thickness of a high-concentration layer in order to suppress the short-channel effect. On the other hand, however, in order to prevent an increase in the series resistance of a source/drain layer, it is desirable that a region where the impurity concentration is at least 1×10²⁰ cm⁻³ or more and preferably 2×10²⁰ cm⁻³ be as large as possible. That is, ideally, the impurity concentration distribution is such that the impurity concentration is maintained at 2×10²⁰ cm⁻³ to a desired depth of about 10 to 20 nm and is sharply reduced beyond that depth.

It is generally known that when RF power is applied to a workpiece substrate through an electrode in a plasma to accelerate and implant positive ions into the workpiece substrate, the positive ion energy has a distribution.

(e.g. M. A. Lieberman and A. J. Lichtenberg, Principles of Plasma Discharges and Materials Processing Second Edition, Wiley Interscience, 2005)

That is, assuming that the incident ion energy is given by E and the energy distribution thereof is given by f(E), the following formula 1 is obtained.

$$\begin{matrix}[ Formula 1 ] & \\ f ( E ) ∝ {\frac{1}{Δ E} [ 1 - ( \frac{E - e {V}_{DC}}{Δ E} ) ]}^{1 / 2} & ( 1 )\end{matrix}$$

Herein, e is the elementary charge and V_{DC} the self-bias voltage generated on the workpiece substrate. Further, ΔE is the energy spread and is expressed by the following formula 2.

$$\begin{matrix}[ Formula 2 ] & \\ Δ E = \frac{2 e {V}_{RF}}{3 ω d} \sqrt{\frac{2 e {V}_{DC}}{{m}_{i}}} & ( 2 )\end{matrix}$$

Herein, V_{RF} is the amplitude of the RF voltage on the workpiece substrate surface, ω the angular frequency of the RF power, d the thickness of a sheath formed between the workpiece substrate surface and a plasma, and mᵢ the mass of an incident ion. As seen from the formula (1), the incident ion energy has an energy spread of 2ΔE and is distributed from the minimum energy eV_{DC}−ΔE to the maximum energy eV_{DC}+ΔE with sharp peaks at the minimum energy and the maximum energy. However, since ΔE is inversely proportional to the frequency of the RF power and to the square root of the ion mass mᵢ, the energy spread decreases as the frequency increases or when heavier ions are used. As a result, in this embodiment, the energy distribution of BF₂⁺ ions reaching the substrate surface was as shown in FIG. 1(a).

It is known that when monoenergetic ions are implanted into silicon, the energy has a Gaussian distribution with a width ΔRp around the average implantation depth Rp. That is, assuming that the dependence of the implanted ion density on the depth x direction, i.e. the implantation depth distribution, is given by n(x), the following formula 3 is obtained.

$$\begin{matrix}[ Formula 3 ] & \\ n ( x ) = \frac{{N}_{0}}{\sqrt{2 π} Δ {R}_{p}} exp [ - {( \frac{x - {R}_{p}}{\sqrt{2} Δ {R}_{p}} )}^{2} ] & ( 3 )\end{matrix}$$

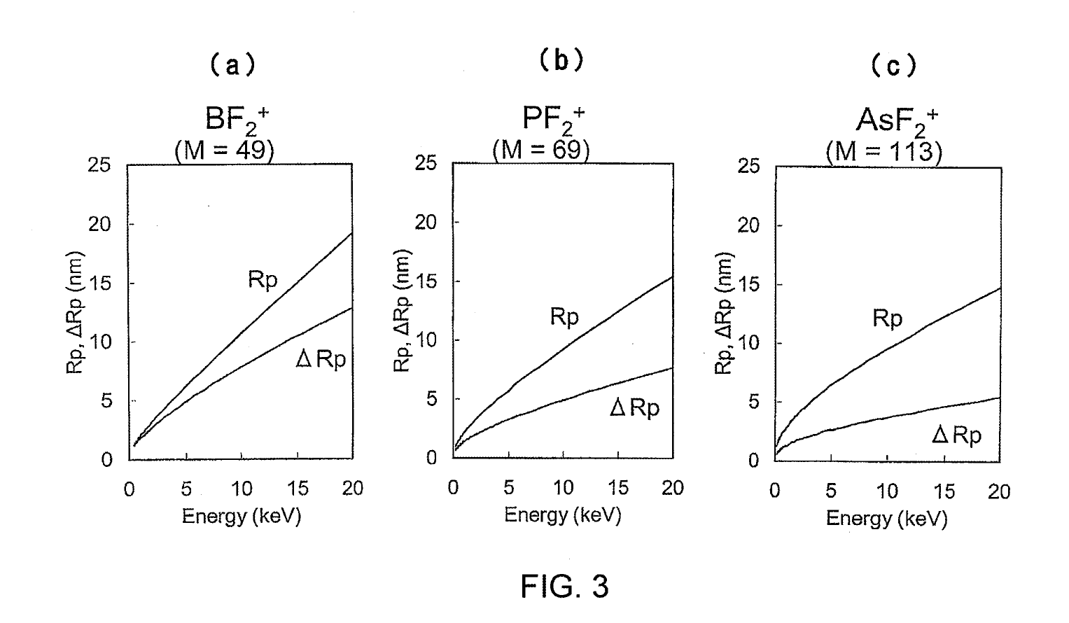

N₀ is the total implantation amount expressed in unit of cm⁻². Rp and ΔRp depend on the incident ion energy and exhibit the dependences for BF₂⁺, PF₂⁺, and AsF₂⁺ as shown in FIGS. 3 (a), (b), and (c), respectively.

In this embodiment, first, BF₂⁺ ions were implanted while being accelerated to 5 keV by generating the self-bias voltage of −5 kV, thus forming a region of 1×10²⁰ cm⁻³ or more to a depth of about 13 nm as shown in FIG. 1(b). By carrying out the implantation while dividing it into 70,000 times pulses, it was possible to suppress charge-up damage. The pulse width and the pulse interval of the RF power were set to 10 μs and 90 μs, respectively. By this implantation, the silicon substrate was amorphized so that it was possible to carry out later dopant activation at a relatively low temperature of about 550° C. to 600° C. However, only by this implantation, the B concentration at the outermost surface did not reach 2×10²⁰ cm⁻³. That is, when a metal electrode is subsequently formed on this surface, the contact resistance with the metal does not become sufficiently low. Accordingly, as shown in FIG. 1(b), while setting the implantation energy to 0.3 keV, BF₂⁺ ions were implanted using 30,000 times pulses for increasing the concentration at the outermost surface, thereby obtaining a final implantation distribution. The total implantation amount was 3×10¹⁴ cm⁻². The B concentration at the outermost surface reached 2×10²⁰ cm⁻³ so that it was possible to realize the low-resistance contact.

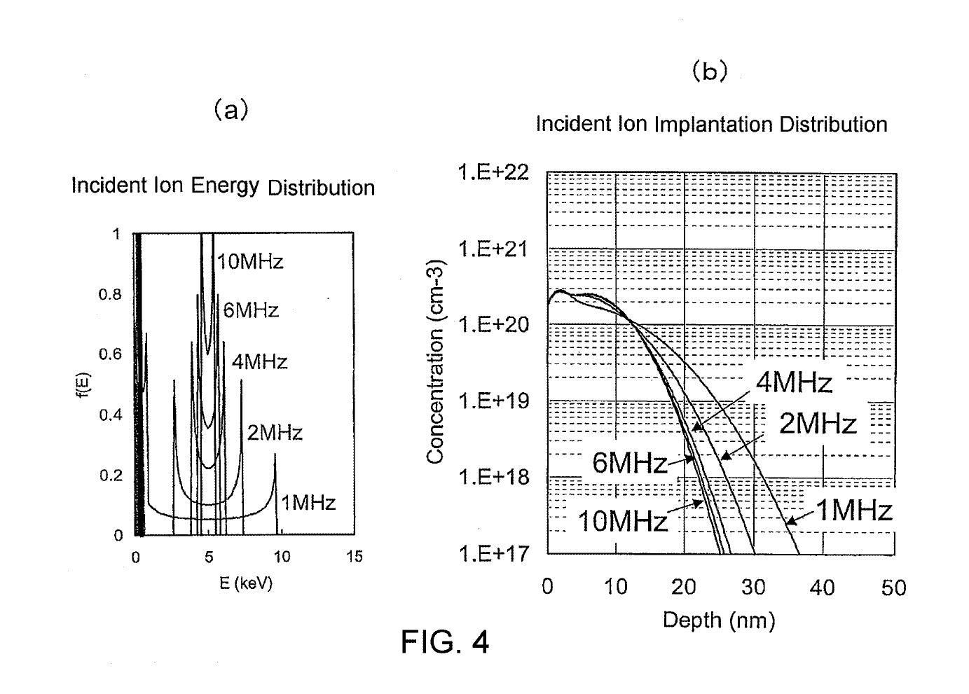

Next, using FIG. 4(a) and FIG. 4(b), a description will be given of an effect of changing the frequency of the substrate RF power. FIG. 4(a) and FIG. 4(b) respectively show the implanted ion energy distribution and the depth-direction dependence of the implanted ion density when pulse application was first carried out 70,000 times by setting the self-bias voltage to −5 kV and, successively, pulse application was carried out 30,000 times by setting the self-bias voltage to −0.3 kV, thereby implanting BF₂⁺ ions in the total implantation amount of 3×10¹⁴ cm⁻². FIG. 4(a) and FIG. 4(b) each show cases where the pulse width and the pulse interval of the RF power were set to 10 μs and 90 μs, respectively, and the frequencies of the RF power were set to 1 MHz, 2 MHz, 4 MHz, 6 MHz, and 10 MHz, respectively. As seen from FIG. 4(a), as the frequency increases, the energy distribution converges to 5 keV and 0.3 keV and, correspondingly, as shown in FIG. 4(b), the implantation distribution is also localized in a shallower region and thus becomes sharp. However, the implantation distribution has a spread of ΔRp even in the case of monoenergetic ions as given by the formula (3) and, accordingly, it is seen that the implantation distribution does not largely change at frequencies of 6 MHz or more. The power for generating the same self-bias voltage increases as the RF frequency increases and thus, in that sense, the lower frequency is desirable. As a consequence, the RF frequency is preferably 4 MHz or more and desirably about 6 MHz as the condition for providing a sharper distribution and for avoiding the need for a large RF power.

Next, a description will be given of one example of a method of setting the pulse width, the pulse interval, and the ion current density. In the ion implantation, ions having a positive charge are implanted while secondary electrons having a negative charge are forced out, and therefore, an ion implanted region is charged positive. In the case of source/drain region implantation, it is necessary to implant ions of about 10¹⁴ cm⁻² as an ion dose. If about 10 secondary electrons are emitted due to one-time ion bombardment, large positive charges of 1×10¹⁵ cm⁻² are accumulated. As a consequence, a strong electric field is generated on a gate insulating film to cause charge-up damage. In order to prevent the generation of the strong electric field, it is preferable to carry out the ion implantation by dividing it into a plurality of times using pulses. That is, it is possible to suppress the generation of the strong electric field by neutralizing the charge-up between the pulses using electrons that are diffused from a plasma exciting region.

For example, a description will be given of the case where ion implantation is carried out while being divided into 100,000 times. That is, when the substrate RF power is applied in the form of pulses while exciting a microwave plasma, the self-bias voltage is generated only when the RF power is turned on so that ion implantation is carried out. When the RF power is off, charge-up is removed by electrons in the plasma. Since the total dose is 3×10¹⁴ cm⁻², the one-time dose is 3×10⁹ cm⁻². The time for neutralizing, by the use of electrons, the charge which is charged positive on a wafer by a one-time pulse, i.e. the pulse interval, was set to be 10 times the pulse width. More generally, with respect to the pulse width and the pulse interval, if the pulse interval is longer than the product of an inverse number of the ratio of electrons to the total number of ion charges in a unit volume in the plasma, a secondary electron emission coefficient of the workpiece substrate, and the pulse width, it is possible to sufficiently remove the charge-up.

In order to process one wafer in 10 seconds, the pulse width for applying the substrate RF power was set to 10 μs while the time for neutralization by electrons was set to 90 μs. Since almost all ions irradiated to the wafer were BF₂⁺, the necessary ion current density J was set to the following formula 4.

$$J = \frac{3 \times {10}^{9} ( {cm}^{- 2} ) \times 1.6 \times {10}^{- 19} ( Q )}{{10}^{- 5} ( s )} = 48 μ A \text{/} {cm}^{2} \qquad [ Formula 4 ]$$

Since the current density is proportional to the plasma density if the electron temperature is constant, the current density may be controlled by changing the plasma density using the plasma excitation microwave power or by adjusting the distance between the workpiece substrate and the plasma exciting region. Since the non-application time was 10 times the RF application time, it was possible to carry out the ion implantation without causing charge-up. More generally, the necessary ion current density J is given by the following formula 5.

$$J = \frac{De}{N Δ t} \qquad [ Formula 5 ]$$

Herein, D is the dose, e the elementary charge, N the number of times of pulses, and Δt the pulse width. It is assumed herein that the implantation ions are ionized to be monovalent. On the other hand, if multivalent ions are present, the elementary charge e may be multiplied by valences to derive the current densities for the ions with the respective valences, thereby setting the sum value as a current density.

### Second Embodiment

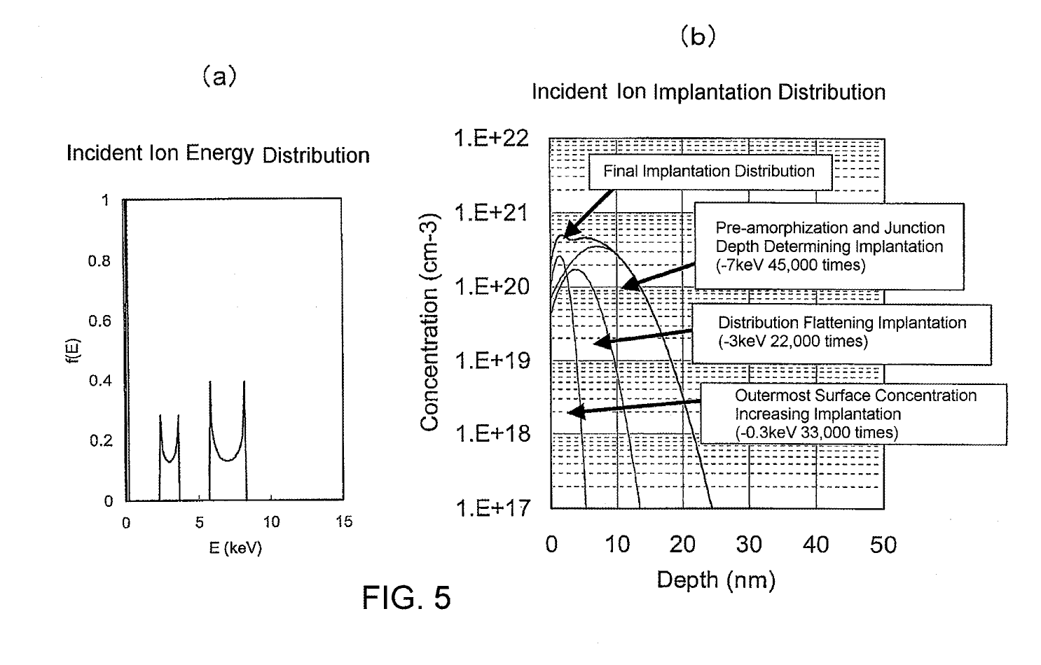

Next, a description will be given of implantation of PF₂⁺ ions for forming an n⁺-Si source/drain region. Explanation of portions overlapping the first embodiment will be omitted. FIG. 5(a) and FIG. 5(b) respectively show the incident ion energy distribution and the incident ion implantation distribution when plasma excitation was carried out using a PF₃ gas so that PF₂⁺ ions were implanted. The RF power frequency was 4 MHz while the self-bias voltage and the number of times of pulse application were changed in order as follows.

| | | |
|---|---|---|
| First | −7 kV | 45,000 times |
| Second | −3 kV | 22,000 times |
| Third | −0.3 kV | 33,000 times |

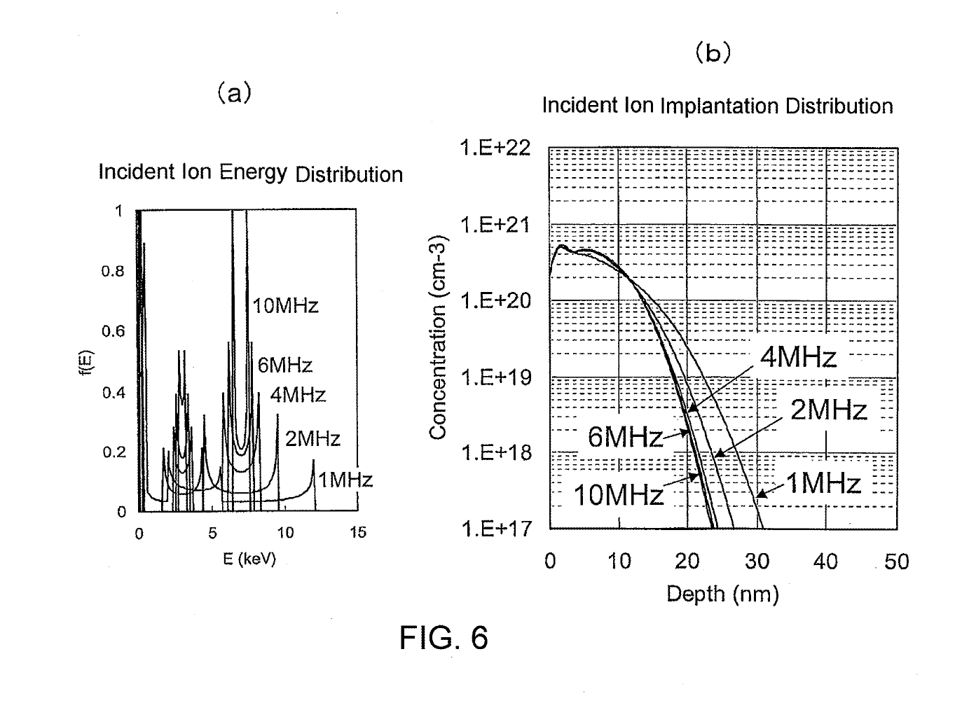

The total implantation amount was set to 5×10¹⁴ cm⁻². Since a PF₂⁺ ion has a larger size and mass as compared with a BF₂⁺ ion, both Rp and ΔRp become smaller with the same implantation energy as shown in FIG. 3. Accordingly, it is seen that the implantation distribution tends to reflect the energy distribution and thus tends to be nonuniform. Therefore, while the self-bias was changed in two ways in the case of BF₂⁺ ions, three self-bias voltages were used by introducing second implantation for flattening the implantation distribution in the case of PF₂⁺ ions. Also in this case, it is preferable to carry out implantation in order of greater absolute values of the self-bias voltages and thus to carry out lower-energy implantation in order while promoting pre-amorphization. FIG. 6(a) and FIG. 6(b) respectively show the incident ion energy distribution and the incident ion implantation distribution when the RF frequency was changed to 1 MHz, 2 MHz, 4 MHz, 6 MHz, and 10 MHz. As in the case of BF₂⁺ ions shown in FIG. 4, the RF frequency is preferably 4 MHz or more and desirably about 6 MHz as the condition for providing a sharp implantation distribution and for avoiding the need for a large RF power.

### Third Embodiment

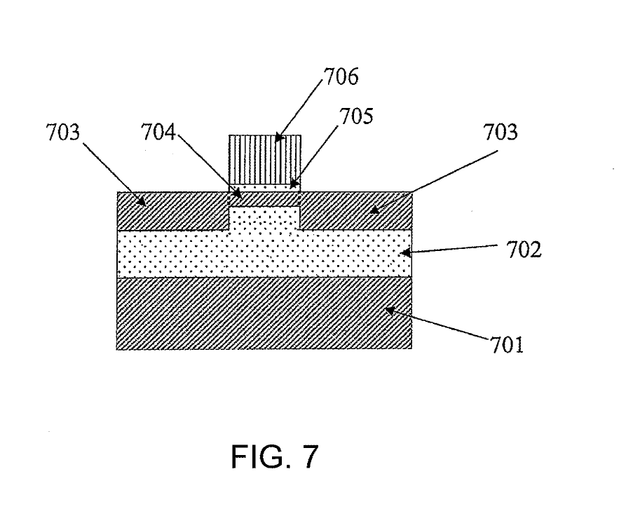

FIG. 7 shows a third embodiment of this invention. Explanation of portions overlapping the first and second embodiments will be omitted. FIG. 7 shows a MOSFET formed on an SOI (Silicon on Insulator) substrate. 701 denotes a silicon bulk substrate, 702 a buried oxide film layer, 703 source/drain regions of an SOI layer, 704 a channel region of the SOI layer, 705 a gate insulating film, and 706 a gate electrode. The thickness of the channel region SOI layer is 25 nm. In order to reduce the series resistance of the source/drain, the source/drain layer SOI layer is required to have a thickness of about the same 25 nm. However, when BF₂⁺ ions or PF₂⁺ ions are implanted by plasma doping to provide regions where the concentration of B or P is 2×10²⁰ cm⁻³ or more, the implantation front reaches about 60 nm. Therefore, if the silicon of the source/drain regions 703 has the same 25 nm as the channel region, the ions are implanted even into the buried oxide film layer 702 to cause degradation in characteristics, such as the occurrence of noise in a manufactured device.

When forming, by plasma doping, the highly doped source/drain layer having a thickness equivalent to that of the silicon of the channel region 704, the implantation front becomes about twice the channel region. Therefore, in order to obtain a sufficiently small series resistance of the source/drain and further to prevent the occurrence of noise, the thickness of the silicon of the source/drain regions 703 should be set to be twice or more that of the silicon of the channel region 704.

As shown in FIG. 7, in this invention, the thickness of the silicon of the source/drain regions 703 was set to 70 nm to thereby satisfy this condition. As a consequence, there was realized an SOIMOSFET having a sufficiently small series resistance of the source/drain and adapted to prevent the occurrence of noise. The same effect can be obtained regardless of whether the MOSFET is an inversion mode in which the channel region and the source/drain regions are of different conductivity types or an accumulation mode in which the channel region and the source/drain regions are of the same conductivity type (WO 2008/007749 A1).

### Fourth Embodiment

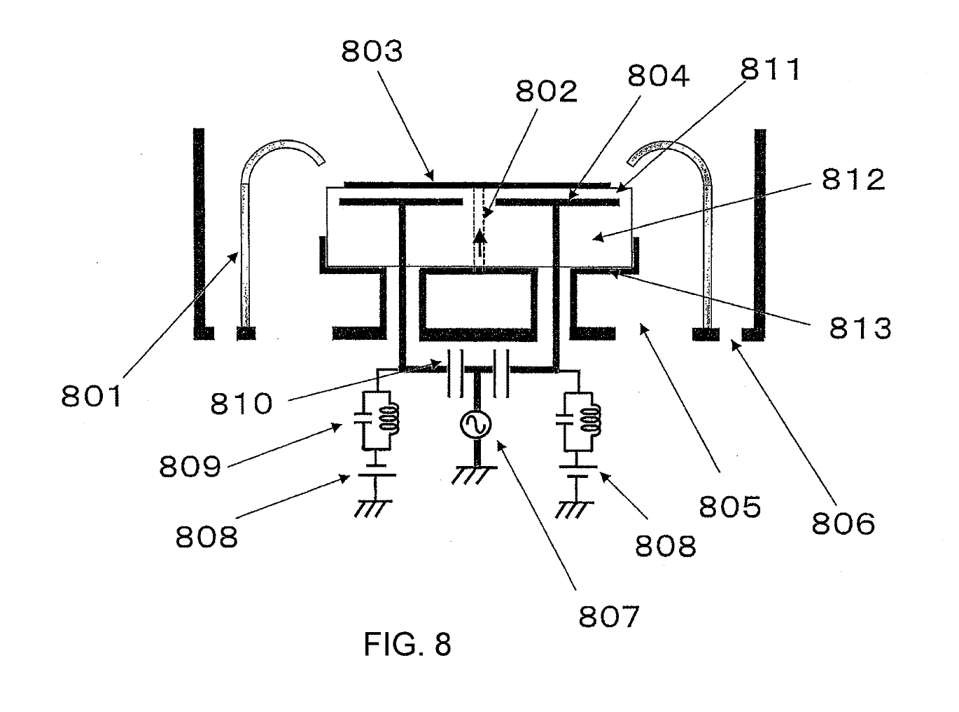

A fourth embodiment of this invention is shown using FIG. 8. FIG. 8 is a detailed diagram around the substrate electrode stage in FIG. 2. 801 denotes a He gas control plate, 802 a He gas introducing portion, 803 a silicon wafer, 804 a substrate electrode for electrostatic chucking and for applying RF power, 805 an exhaust port inside the He gas control plate, 806 an exhaust port outside the He gas control plate, 807 an RF power supply, 808 electrostatic-chuck DC power supplies (one outputs a positive voltage while the other outputs a negative voltage), 809 parallel resonant filters, 810 blocking capacitors, 811 a conductive ceramic, 812 an insulating ceramic, and 813 a ground plate.

The conductive ceramic 811 has a resistivity controlled to about 10¹⁰ Ωcm at room temperature and a thickness of 1 mm. The insulating ceramic 812 has a relatively large thickness of 2 cm to thereby make small the capacitance between the ground plate 813 and the substrate electrode 804.

With this structure, when the RF power is applied to the substrate electrode 804, it is possible to efficiently generate a self-bias. The substrate electrode 804 uses a bipolar chuck so that, by applying +500V to an electrode on one side and −500V to the other electrode from the DC power supplies 808, the silicon wafer 803 is attracted. Using the bipolar chuck, both charges cancel each other out in the wafer. Accordingly, no voltage due to the DC power supplies occurs in the wafer 803 so that it is possible to control the self-bias voltage only by the RF power applied from the RF power supply 807. The DC power supplies 808 are connected to the substrate electrode through the parallel resonant filters 809, respectively. In the parallel resonant filters 809, the resonant frequency is set to the frequency of the RF power so that the impedance takes an extremely large value at that frequency. As a consequence, the RF power is prevented from being supplied to the DC power supply 808 sides. Between the wafer and the conductive ceramic, a He gas is filled through the He gas introducing portion 802 and the pressure is set to 10 Torr by adjusting the He gas flow rate. This makes it possible to ensure the thermal conductivity between the wafer and the conductive ceramic and thus to efficiently remove the heat generated during ion implantation. If the He gas returns to a plasma exciting region, the He gas is ionized to He ions. The He ions are very light and thus are accelerated by the self-bias voltage so as to be implanted at high energy into the wafer, thus serving as a factor to cause damage.

In order to prevent it, the He gas control plate 801 is disposed around the conductive ceramic. By this control plate, the He gas leaking from the outer periphery of the wafer is exhausted from the inner exhaust port 805. This makes it possible to prevent the He gas from returning to the plasma exciting region and thus to prevent ionization of the He gas. A plasma excitation gas is exhausted from both the inner exhaust port 805 and the outer exhaust port.

While the invention made by the present inventors has been described in detail with reference to the embodiments, it is needless to say that this invention is not limited to the above-mentioned embodiments and can be changed in various ways without departing from the gist of the invention.

### INDUSTRIAL APPLICABILITY

This invention is not only applicable to the manufacture of semiconductor devices, but also applicable to the manufacture of various electronic devices such as flat display devices.

1. An ion implantation apparatus, comprising:
a processing chamber which is evacuated and in which a plasma is excited and,
a holding stage provided in the processing chamber and holding a substrate to be processed,
wherein an RF power is applied to the holding stage to generate a self-bias voltage on a surface of the substrate so that positive ions in the plasma are accelerated and implanted into the substrate,
wherein the RF power has a frequency of 4 MHz or more and is applied in the form of pulses so that ion implantation is dividedly carried out a plurality of times.

2. The ion implantation apparatus according to claim 1, wherein the plasma is excited by causing an electromagnetic wave having a frequency selected from a range of 100 MHz to 3 GHz to propagate as a metal surface wave into the processing chamber and
introducing a gas for plasma excitation into the processing chamber.

3. The ion implantation apparatus according to claim 1, wherein the holding stage has an electrostatic chuck function,
a gas is filled into a space between the holding stage and the substrate by the electrostatic chuck function,
a filling pressure of the gas is set higher than a pressure in the processing chamber, and
a shield plate is provided around the holding stage for preventing the gas leaking from the space from entering a plasma exciting region.

4. An ion implantation method that carries out ion implantation using the ion implantation apparatus according to claim 1.

5. The ion implantation method according to claim 4, wherein the ion implantation is carried out using at least a plurality of self-bias voltages by changing the RF power to be applied to the holding stage.

6. The ion implantation method according to claim 5, wherein the surface of the substrate comprises a semiconductor crystal containing silicon, the method comprising:
a step of carrying out the ion implantation while amorphizing the semiconductor crystal by at least a first self-bias voltage, and
a step of causing an ion implantation density of an outermost surface of the semiconductor crystal to be at least 1×10²⁰ cm⁻³ or more by a second self-bias voltage.

7. The ion implantation method according to claim 4, wherein the gas for plasma excitation is a gas of a fluoride of an implantation atom.

8. The ion implantation method according to claim 4, wherein the gas for plasma excitation is at least one gas selected from the group comprising BF₃, PF₃, and AsF₃.

9.-10. (canceled)

11. A semiconductor device manufactured using the ion implantation apparatus according to claim 1.

12. A semiconductor device manufactured using the ion implantation method according to claim 6.

13. A semiconductor device manufacturing method, comprising:
a step of carrying out ion implantation by the ion implantation method according to claim 4.

14. The ion implantation apparatus according to claim 1, wherein a pulse width of the RF power is shorter than a pulse stop period of the RF power.

15. A semiconductor device manufactured using the ion implantation method according to claim 7.
